(19) United States
(12) Patent Application Publication
(10) Pub. No.: US 2024/0315097 A1
(43) Pub. Date: Sep. 19, 2024

(54) DISPLAY PANEL

(71) Applicant: Guangzhou China Star Optoelectronics Semiconductor Display Technology Co., Ltd., Guangzhou (CN)

(72) Inventor: Ximan LIU, Guangzhou (CN)

(21) Appl. No.: 18/517,305

(22) Filed: Nov. 22, 2023

(30) Foreign Application Priority Data
Mar. 17, 2023 (CN) 202310270242.1

(51) Int. Cl. H10K 59/131

(52) U.S. Cl. CPC H10K 59/131

(57) ABSTRACT

A display panel includes a first fan-out wire, a second fan-out wire and a third fan-out wire in the fan-out routing area are positioned in different layers to save the space for arranging a fan-out route in a horizontal direction. The second fan-out wire partially overlaps with the first and third fan-out wires. This could further shorten the horizontal distance between the fan-out wires, thereby realizing a narrow frame. Because the second fan-out wire partially overlaps the first and third fan-out wires, respectively, the parasitic capacitance between the fan-out wires is reduced, and thus the data signal interference is reduced.

### CROSS REFERENCE TO RELATED APPLICATION

This application claims the priority of Chinese Patent Application No. 202310270242.1, entitled “DISPLAY PANEL”, filed on Mar. 17, 2023, the disclosure of which is incorporated herein by reference in its entirety.

### FIELD OF THE DISCLOSURE

The present disclosure relates to a display technology, and more particularly to a display panel.

### BACKGROUND

Display panels with a large size, a high resolution and an ultra-narrow have become the trend of the market development. High resolution requires more data wires in a limited space and also needs more fan wires to connect the data signals of pixels and pins of the source driver chip. The spacing between the fan wires basically determines the size of the side frame of the display panel.

Conventionally, the fan-out wires in the fan-out area generally adopt single-layer metal wires or double-layer metal wires. However, due to the large number of data lines, the width of accumulated fan-out wires is very large and thus makes it difficult to realize a narrow side frame.

### SUMMARY

One objective of an embodiment of the present disclosure is to provide a display panel to realize a narrow side frame.

According to an embodiment of the present disclosure, a display panel is disclosed. The display panel comprises: a substrate, having a display area and a fan-out routing area located on one side of the display area; a plurality of data lines, positioned in the display area; a plurality of wiring groups, positioned in the fan-out routing area, wherein the wiring group comprises a first fan-out wire, a second fan-out wire, and a third fan-out wire positioned in different layers, and one of the data lines is connected to one of the fan-out wire, the second fan-out wire, and the third fan-out wire. In an orthographic projection direction of the substrate, the first fan-out wire and the second fan-out wire partially overlap, and the second fan-out wire and the third fan-out wire partially overlap.

Optionally, in some embodiments of the present disclosure, the first fan-out wire comprises a first fan-out segment, the second out-out wire comprises a second fan-out segment, the third out-out wire comprises a third fan-out segment; an extension direction of the first fan-out segment, the second fan-out segment and the third fan-out segment all intersect with an extension direction of the data line; in a pattern of the orthographic projection direction of the substrate, the first fan-out segment is located on one side of the second fan-out segment, the third fan-out segment is located on another side of the second fan-out segment, a portion of the second fan-out segment is partially overlapped with a portion of the first fan-out segment, and a portion of the second fan-out segment is partially overlapped with a portion of the third fan-out segment.

Optionally, in some embodiments of the present disclosure, in one of the wiring groups, extension directions of the first fan-out segment, the second fan-out segment, and the third fan-out segment are parallel.

Optionally, in some embodiments of the present disclosure, in a direction from a side edge of the fan-out routing area to a middle of the fan-out routing area, an inclination angle of the first fan-out segment increases.

Optionally, in some embodiments of the present disclosure, in a direction from a side edge of the fan-out routing area to a middle of the fan-out routing area, lengths of the first fan-out segment, the second fan-out segment, and the third fan-out segment in a same wiring group sequentially decreases.

Optionally, in some embodiments of the present disclosure, in a direction from a side edge of the fan-out routing area to a middle of the fan-out routing area, lengths of the first fan-out segments in the plurality of wiring groups sequentially decreases.

Optionally, in some embodiments of the present disclosure, one of the first fan-out wire, the second fan-out wire, and the third fan-out wire is provided on a same layer as the data lines.

Optionally, in some embodiments of the present disclosure, the first fan-out wire further comprises a first connection segment connected to one end of the first fan-out segment and a first binding segment connected to another end of the first fan-out segment; and extension directions of the first connection segment and the first binding segment both intersect the extension direction of the first fan-out segment. The second fan-out wire further comprises a second connecting segment connected to one end of the second fan-out segment and a second binding segment connected to another end of the second fan-out segment; and extension directions of the second connecting segment and the second binding segment both intersect the extension direction of the second fan-out segment. The third fan-out wire further comprises a third connecting segment connected to one end of the third fan-out segment and a third binding segment connected to the other end of the third fan-out segment; and extension directions of the third connecting segment and the third bound segment both intersect the extension direction of the third fan-out segment.

Optionally, in some embodiments of the present disclosure, the plurality of data lines include a first data line, a second data line and a third data line, the second fan-out wire is provided in a same layer as the data lines; the first fan-out wire is located below the second fan-out wire, and the third fan-out wire is located above the second fan-out wire. The display panel further comprises a first adapter portion and a second adapter portion located in a same layer, and the first adapter portion and the second adapter portion are located above the wiring groups. One end of the first adapter portion is connected to the first data line, and another end of the first adapter portion is connected to the first connection segment. The second connection segment is directly connected to the second data line. One end of the second adapter portion is connected to the third data line, and another end of the second adapter portion is connected to the third connection segment.

Optionally, in some embodiments of the present disclosure, the display panel further includes a first insulating layer, a second insulating layer, a third insulating layer, and a fourth insulating layer. The first insulating layer covers the first fan-out wire and the substrate. The data line and the second fan-out wire are disposed on the first insulating layer. The second insulating layer covers the second fan-out wire, the data line and the first insulating layer. The third insulating layer covers the second insulating layer. The third fan-out wire is disposed on the third insulating layer. The fourth insulating layer covers the third fan-out wire and the third insulating layer. The first adapter portion and the second adapter portion are disposed on the fourth insulating layer.

According to an embodiment of the present disclosure, a display panel is disclosed. The display panel comprises: a substrate, having a display area and a fan-out routing area located on one side of the display area; a plurality of data lines, positioned in the display area; a plurality of wiring groups, positioned in the fan-out routing area, wherein the wiring group comprises a first fan-out wire, a second fan-out wire, and a third fan-out wire positioned in different layers, and one of the data lines is connected to one of the fan-out wire, the second fan-out wire, and the third fan-out wire. In an orthographic projection direction of the substrate, the first fan-out wire and the second fan-out wire partially overlap, and the second fan-out wire and the third fan-out wire partially overlap.

According to an embodiment, the first fan-out wire, the second fan-out wire and the third fan-out wire in the fan-out routing area are positioned in different layers to save the space for arranging the fan-out route in the horizontal direction. Furthermore, the second fan-out wire partially overlaps with the first and third fan-out wires. This could further shorten the horizontal distance between the fan-out wires, thereby realizing a narrow frame. In addition, because the second fan-out wire partially overlaps the first and third fan-out wires, respectively, the parasitic capacitance between the fan-out wires is reduced, and thus the data signal interference is reduced.

### BRIEF DESCRIPTION OF THE DRAWINGS

In order to more clearly illustrate the technical solution in the embodiment of the present disclosure, the following will be a brief introduction to the drawings required in the description of the embodiment. Obviously, the drawings described below are only some embodiments of the present disclosure, for those skilled in the art, without the premise of creative labor, may also obtain other drawings according to these drawings.

FIG. 1 is a diagram of a display panel according to an embodiment of the present disclosure.

FIG. 2 is a magnified view of part A in FIG. 1.

FIG. 3 is a diagram of a wiring group of the display panel according to an embodiment of the present disclosure.

FIG. 4 is a diagram of a cross-sectional structure of the display panel according to an embodiment of the present disclosure.

### DETAILED DESCRIPTION OF PREFERRED EMBODIMENTS

The technical solutions in the embodiments of the present application will be clearly and completely described below with reference to the accompanying drawings in the embodiments of the present application. Obviously, the described embodiments are only some of the embodiments of the present application, rather than all of the embodiments. Based on the embodiments in this application, all other embodiments obtained by those skilled in the art without making creative efforts fall within the scope of protection of this application. In addition, it should be understood that the specific embodiments described here are only used to illustrate and explain the application, and are not used to limit the application. In this application, unless otherwise specified, the directional words used such as “upper” and “lower” usually refer to the upper and lower positions of the device in actual use or working conditions, specifically the direction of the drawing in the drawings. The terms “inside” and “outside” refer to the outline of the device.

An embodiment of the present disclosure provides a display panel, which will be described in detail below. It should be noted that the order of description of the following embodiments does not limit the preferred order of the embodiments.

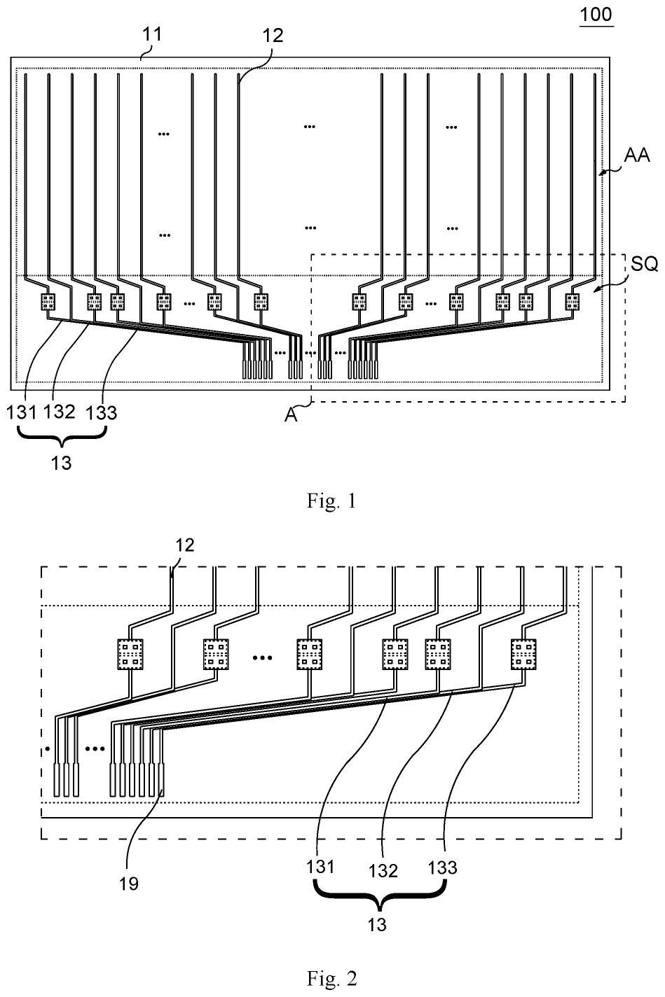

Please refer to FIGS. 1 and 2. A display panel 100 is disclosed. The display panel 100 comprises a substrate 11, a plurality of data lines 12 and a plurality of wiring groups 13.

The substrate 11 has a display area AA and a fan-out routing area SQ located on a side of the display area AA. The plurality of data lines 12 are positioned in the display area AA. The plurality of wiring groups 13 are positioned in the fan-out routing area SQ.

A wiring group 13 comprises a first fan-out wire 131, a second fan-out wire 132 and a third fan-out wire 133 disposed in different layers. A data line 12 is correspondingly connected to one of the first fan-out wire 131, the second fan-out wire 132 and the third fan-out wire 133.

In an orthogonal projection direction of the substrate 11, the first fan-out wire 131 and the second fan-out wire 132 partially overlap, and the second fan-out wire 132 and the third fan-out wire 133 partially overlap.

In this embodiment, the first fan-out wire 131, the second fan-out wire 132 and the third fan-out wire 133 are positioned in different layers in the fan-out wiring routing area SQ. This reduces the horizontal layout space of the wiring group 13. The second fan-out wire 132 respectively partially overlap with the first fan-out wire 131 and the third fan-out wire 133. This further shortens the horizontal distance between the fan-out wires, thereby making a narrow frame possible. Furthermore, this further reduce the parasitic capacitance between the fan out wires and thus also reduce the risk of data signal interference.

Optionally, the first fan-out wire 131 may be selected from metal elements including chromium (Cr), copper (Cu), aluminum (Al), gold (Au), silver (Ag), zinc (Zn), molybdenum (Mo), tantalum (Ta), titanium (Ti), tungsten (W), manganese (Mn), nickel (Ni), iron (Fe), and cobalt (Co), alloys composed of any of the above metal elements, or alloys combining any of the above metal elements. Furthermore, the first fan-out wire 131 may have a single-layer structure or a stacked structure of more than two layers.

The material and structure of the second fan-out wire 132 and the third fan-out wire 133 could be the same as the material and structure of the first fan-out wire 131. However, in some embodiments, the materials of the three fan-out wires may also be different.

Optionally, the first fan-out wire 131 includes a first fan-out segment 1a. The second fan-out wire 132 includes a second fan-out segment 2a. The third fan-out wire 133 includes a third fan-out segment 3a. The extension direction of the first fan-out segment 1a, the second fan-out segment 2a and the third fan-out segment 3a all intersect the extension direction of the data line 12.

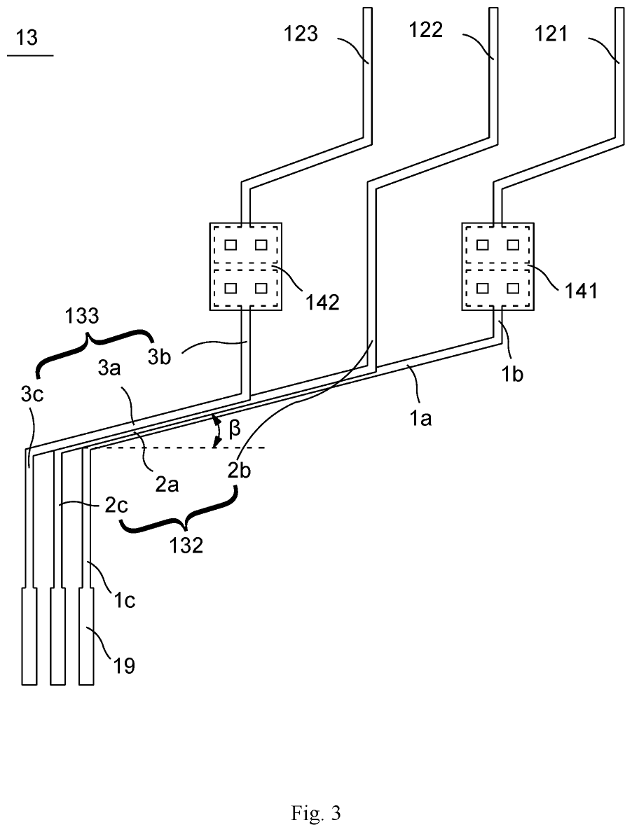

As shown in FIGS. 2 and 3, in the pattern of the orthographic projection direction of the substrate 11, the first fan-out segment 1a is located on one side of the second fan-out segment 2a, and the third fan-out segment 3a is located on the other side of the second fan-out segment 2a. The portion of the second fan-out segment 2a partially overlaps with the portion of the first fan-out segment 1a, and the portion of the second fan-out segment 2a partially overlaps with the portion of the third fan-out segment 3a.

The first, second and third fan-out segments (la, 2a, and 3a) extend and overlap in the length direction.

Optionally, the overlapping width of the first and second fan-out segments (1a, 2a) is half the width of the second fan-out segment 2a. The overlapping width of the third and second fan-out segments (3a, 2a) is also half the width of the second fan-out segment 2a.

For example, if the line width of the first fan-out segment 1a, the second fan-out segment 2a and the third fan-out segment 3a is 3 microns, the overlapping width of the first and second fan-out segments (1a, 2a) is 1.5 microns, and the overlapping width of the third and second fan-out segments (3a, 2a) is also 1.5 microns.

Optionally, the overlapping width of the first and second fan-out segments (1a, 2a) may be less than half of the width of the second fan-out segment 2a. The overlapping width of the third and second fan-out segments (3a, 2a) may also be less than half of the width of the second fan-out segment 2a to reduce parasitic capacitance.

Optionally, in a wiring group 13, the extension directions of the first fan-out segment 1a, the second fan-out segment 2a and the third fan=out segment 3a are parallel. It could be understood that the extension directions of the three are arranged in parallel, so that the overlapping area of the first fan-out segment 1a and the second fan-out segment 2a and the overlapping area of the second fan-out segment 2a and the third fan-out segment 3a can be larger. This reduces distance required for wiring is shorter and thus further reduces their overall width.

Optionally, the extension directions of the first fan-out segment 1a, the second fan-out segment 2a and the third fan-out segment 3a may also be intersecting. For example, the angle between the extension directions of the first fan-out segment 1a and the second fan-out segment 2a can be lower than 3 degrees and the angle between the extension directions of the second fan-out segment 2a and the third fan-out segment 3a may also be lower than 3 degrees. The closer the angle between any two directions is to 0, the more area the two fan-out wires can overlap in the length direction, and the greater the space that can be reduced.

Optionally, in the direction from the side edge of the fan-out routing area SQ to the middle of the fan-out routing area SQ, the inclination angle β of the first fan-out segment 1a is increasing.

In the direction from the side edge of the fan-out routing area SQ to the middle of the fan-out routing area SQ, among a plurality of wiring groups 13, the lengths of the first fan-out segments 1a sequentially decreases.

It is noted that the angle β is the angle between the extension direction of the first fan-out segment 1a and the direction of the scan line. Because the inclination angle β of the first fan-out segment 1a increases and the binding terminals of the binding area are arranged in parallel, the increased inclination angle of the first fan-out segment 1a makes the length of the first fan-out segment 1a become shorter when it becomes closer to the middle area. Thus, it can save the material of the wire. In addition, because in the same wiring group 13, the first fan-out segment 1a, The second fan-out segment 2a and the third fan-out segment 3a are arranged in parallel, so the inclination angle of the wiring group 13 is increasing along with the inclination angle of the first fan-out segment 1a. In this way, on the side close to the display area AA, the spacing between the wiring groups 13 will be incremented to reduce the risk of signal interference and reduce the manufacturing difficulty.

Optionally, in the direction from the side edge of the fan-out routing area SQ to the middle of the fan-out routing area SQ, in the same wiring group 13, the lengths of the first fan-out segment 1a, the second fan-out segment 2a and the third fan-out segment 3a decreases sequentially.

Optionally, in some embodiments, in the direction from the side edge of the fan-out routing area SQ to the middle of the fan-out routing area SQ, among a plurality of wiring groups 13, the overlapping area of the first fan-out segment 1a and the second fan-out segment 2a increases, and the overlapping area of the second fan-out segment 2a and the third fan-out segment 3a also increases. When the length of the fan-out segment closer to the edge region is longer, the impedance become greater. In this embodiment, the overlapping area close to the edge area is smaller. In this way, the influence of parasitic capacitance becomes smaller, so that the signal transmission synchronization is improved.

Optionally, the pattern of the first fan-out segment 1a is a straight strip with a hollow matrix, the pattern of the second fan-out segment 2a and the third fan-out segment 3a is a solid straight strip. Or, the pattern of the first fan-out segment 1a is a straight strip with a hollow matrix, the pattern of the second fan-out segment 2a is a solid straight strip, and the pattern of the third fan-out segment 3a is in a solid wavy shape. In this way, in the same wiring group 13, the overlapping area of the first fan-out segment 1a and the second fan-out segment 2a is less than the overlapping area of the second fan-out segment 2a and the third fan-out segment 3a.

In the same wiring group 13, the third fan-out segment 3a is close to the middle region, and the first fan-out segment 1a is close to the edge region. Therefore, the above arraignment could improve the signal transmission synchronization.

In addition, because the third fan-out segment 3a is wavy, the length of the third fan-out segment 3a has a longer length than the straight strip structure, so that the length of the third fan-out segment 3a tends to be the same or equivalent to the length of the second fan-out segment 2a and/or the length of the first fan-out segment 1a, thereby improving the signal transmission synchronization.

In the case that the length of the third fan-out segment 3a is substantially equal to the length of the second fan-out segment 2a and/or the length of the first fan-out segment 1a, in the same wiring group 13, the overlapping area of the first fan-out segment 1a and the second fan-out segment 2a is equal to the overlapping area of the second fan-out segment 2a and the third fan-out segment 3a. This further improves the signal transmission synchronization.

Optionally, one of the first fan-out wire 131, the second fan-out wire 132 and the third fan-out wire 133 is positioned in the same layer as the data line 12.

That is, it may be that the first fan-out wire 131 and data line 12 are in the same layer, and the other two wires and the data line 12 are in different layers. Or, the second fan-out wire 132 and data line 12 are in the same layer, and the other two and the data line 12 are in different layers. Or, the third fan-out wire 133 and data line 12 are in the same layer, the other two wires and the data line 12 are in different layers.

In this embodiment, the second fan-out wire 132 and the data line 12 are in the same layer, and the other two wires and data line 12 are in different layers. However, this is an example, not a limitation of the present disclosure.

The first fan-out wire 131 further comprises a first connection segment 1b connected to one end of the first fan-out segment 1a and a first binding segment 1c connected to the other end of the first fan-out segment 1a. The extension direction of the first connecting segment 1b and the first binding segment 1c intersects with the extension direction of the first fan-out segment 1a.

The second fan-out wire 132 further comprises a second connection segment 2b connected to one end of the second fan-out segment 2a and a second binding segment 2c connected to the other end of the second fan-out segment 2a. The extension direction of the second connection segment 2b and the second binding segment 2c intersects with the extension direction of the second fan-out segment 2a.

The third fan-out wire 133 further comprises a third connection segment 3b connected to one end of the third fan-out segment 3a and a third binding segment 3c connected to the other end of the third fan-out segment 3a. The extension direction of the third connection segment 3b and the third binding segment 3c intersects with the extension direction of the third fan-out segment 3a.

The first binding segment 1c, the second binding segment 2c and the third binding segment 3c are respectively connected to a binding terminal 19. A plurality of binding terminals 19 are arranged in a row in the binding area.

In some embodiments, the binding terminals 19 are arranged in three rows. Each row of binding terminals 19 are connected to a type of fan-out wires. For example, the first fan-out wires 131 are connected to the third row of the binding terminals 19, the second fan-out wires 132 are connected to the second row of binding terminals 19, and the third fan-out wires 133 are connected to the first row of binding terminals 19.

Each row of binding terminals 19 and the other two rows of binding terminals 19 are disposed in different layers. The third row of binding terminals 19 is provided on the same layer as the first fan-out wires 131, the second row of binding terminals 19 is provided on the same layer as the second fan-out wires 132, and the first row of binding terminals 19 is provided on the same layer as the third fan-out wires 133.

Optionally, the plurality of data lines 12 comprise a first data line 121, a second data line 122 and a third data line 123. The second fan-out wire 132 is provided in the same layer as the data line 12. The first fan-out wire 131 is located below the second fan-out wire 132, and the third fan-out wire 133 is located above the second fan-out wire 132.

The display panel 100 further comprises a first adapter portion 141 and a second adapter portion 142 positioned in the same layer. The first adapter portion 141 and the second adapter portion 142 are located above the wiring group 13.

One end of the first adapter portion 141 is connected to the first data line 121, and the other end of the first adapter portion 141 is connected to the first connection segment 1b. The second connection segment 2b is directly connected to the second data line 122. One end of the second adapter portion 142 is connected to the third data line 123, and the other end of the second adapter portion 142 is connected to the third connection segment 3b.

Optionally, one end of the first adapter portion 141 is connected to the first data line 121 through at least two vias, and the other end of the first adapter portion 141 is connected to the first connection segment 1b through at least two vias. One end of the second adapter portion 142 is connected to the third data line 123 through at least two vias, and the other end of the first adapter portion 141 is connected to the third connection segment 3b through at least two vias. Multi-via connections are used to reduce impedance.

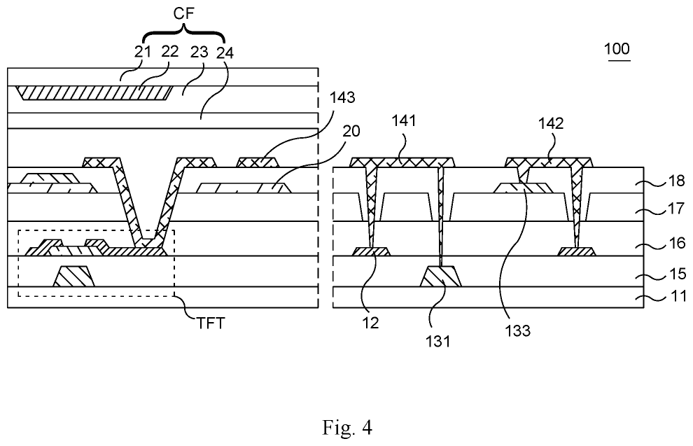

Optionally, please refer to FIG. 4. The display panel 100 further comprises a first insulation layer 15, a second insulation layer 16, a third insulation layer 17 and a fourth insulation layer 18. The first insulation layer 15 covers the first fan-out wire 131 and the substrate 11. The data line 12 and the second exit trace 132 are disposed on the first insulation layer 15. The second insulation layer 16 covers the second fan-out wire 132, the data line 12 and the first insulation layer 15. The third insulation layer 17 covers the second insulation layer 16. The third fan-out wire 133 is disposed on the third insulation layer 17. The fourth insulation layer 18 covers the third fan-out wire 133 and the third insulation layer 17. The first adapter portion 141 and the second adapter portion 142 are disposed on the fourth insulation layer 18.

Optionally, the thickness of the third insulation layer 17 is between 2-3 microns. The third insulation layer 17 is thicker to reduce the parasitic capacitance between the second fan-out wire 132 and the third fan-out wire 133, so that the power consumption could be reduced.

Optionally, the display panel 100 further comprises a thin-film transistor TFT with a bottom-gate structure, a common electrode layer 20 and a pixel electrode 143. The pixel electrode 143 and the first adapter portion 141 are provided in the same layer.

Optionally, the display panel 100 further comprises a color film substrate CF. The color film substrate CF includes another substrate 21, a black matrix 22, a color film layer 23 and a protective layer 24.

In some embodiments, the display panel 100 could be an organic light-emitting diode panel, mini-LED panel or any other electroluminescent panels.

According to an embodiment, the first fan-out wire 131, the second fan-out wire 132 and the third fan-out wire 133 in the fan-out routing area SQ are positioned in different layers to save the space for arranging the wiring group 13 in the horizontal direction. Furthermore, the second fan-out wire 132 partially overlaps with the first fan-out wire 131 and the third fan-out wire 133. This could further shorten the horizontal distance between the fan-out wires, thereby realizing a narrow frame. In addition, because the second fan-out wire 132 partially overlaps the first fan-out wire 131 and the third fan-out wire 133, respectively, the parasitic capacitance between the fan-out wires is reduced, and thus the data signal interference is reduced.

The display panel provided by the embodiments of the present disclosure are described in detail above. The present disclosure uses specific examples to describe principles and embodiments of the present disclosure. The above description of the embodiments is only for helping to understand solutions of the present disclosure and their core ideas. Furthermore, those skilled in the art may make modifications to the specific embodiments and applications according to ideas of the present invention. In conclusion, the present specification should not be construed as a limitation to the present invention.

What is claimed is:

1. A display panel, comprising:
a substrate, having a display area and a fan-out routing area located on one side of the display area;
a plurality of data lines, positioned in the display area;
a plurality of wiring groups, positioned in the fan-out routing area, wherein the wiring group comprises a first fan-out wire, a second fan-out wire, and a third fan-out wire positioned in different layers, and one of the data lines is connected to one of the fan-out wire, the second fan-out wire, and the third fan-out wire;
wherein in an orthographic projection direction of the substrate, the first fan-out wire and the second fan-out wire partially overlap, and the second fan-out wire and the third fan-out wire partially overlap.

2. The display panel of claim 1, wherein the first fan-out wire comprises a first fan-out segment, the second out-out wire comprises a second fan-out segment, the third out-out wire comprises a third fan-out segment; an extension direction of the first fan-out segment, the second fan-out segment and the third fan-out segment all intersect with an extension direction of the data line;
in a pattern of the orthographic projection direction of the substrate, the first fan-out segment is located on one side of the second fan-out segment, the third fan-out segment is located on another side of the second fan-out segment, a portion of the second fan-out segment is partially overlapped with a portion of the first fan-out segment, and a portion of the second fan-out segment is partially overlapped with a portion of the third fan-out segment.

3. The display panel of claim 2, wherein in one of the wiring groups, extension directions of the first fan-out segment, the second fan-out segment, and the third fan-out segment are parallel.

4. The display panel of claim 3, wherein in a direction from a side edge of the fan-out routing area to a middle of the fan-out routing area, an inclination angle of the first fan-out segment increases.

5. The display panel of claim 3, wherein in a direction from a side edge of the fan-out routing area to a middle of the fan-out routing area, lengths of the first fan-out segment, the second fan-out segment, and the third fan-out segment in a same wiring group sequentially decreases.

6. The display panel of claim 3, wherein in a direction from a side edge of the fan-out routing area to a middle of the fan-out routing area, lengths of the first fan-out segments in the plurality of wiring groups sequentially decreases.

7. The display panel of claim 1, wherein one of the first fan-out wire, the second fan-out wire, and the third fan-out wire is provided on a same layer as the data lines.

8. The display panel of claim 7, wherein the first fan-out wire further comprises a first connection segment connected to one end of the first fan-out segment and a first binding segment connected to another end of the first fan-out segment; and extension directions of the first connection segment and the first binding segment both intersect the extension direction of the first fan-out segment;
wherein the second fan-out wire further comprises a second connecting segment connected to one end of the second fan-out segment and a second binding segment connected to another end of the second fan-out segment; and extension directions of the second connecting segment and the second binding segment both intersect the extension direction of the second fan-out segment;
wherein the third fan-out wire further comprises a third connecting segment connected to one end of the third fan-out segment and a third binding segment connected to the other end of the third fan-out segment; and extension directions of the third connecting segment and the third bound segment both intersect the extension direction of the third fan-out segment.

9. The display panel of claim 8, wherein the plurality of data lines include a first data line, a second data line and a third data line, the second fan-out wire is provided in a same layer as the data lines; the first fan-out wire is located below the second fan-out wire, and the third fan-out wire is located above the second fan-out wire;
wherein the display panel further comprises a first adapter portion and a second adapter portion located in a same layer, and the first adapter portion and the second adapter portion are located above the wiring groups;
wherein one end of the first adapter portion is connected to the first data line, another end of the first adapter portion is connected to the first connection segment; the second connection segment is directly connected to the second data line; one end of the second adapter portion is connected to the third data line, and another end of the second adapter portion is connected to the third connection segment.

10. The display panel of claim 9, further comprising a first insulating layer, a second insulating layer, a third insulating layer, and a fourth insulating layer; wherein the first insulating layer covers the first fan-out wire and the substrate; the data line and the second fan-out wire are disposed on the first insulating layer; the second insulating layer covers the second fan-out wire, the data line and the first insulating layer; the third insulating layer covers the second insulating layer; the third fan-out wire is disposed on the third insulating layer; the fourth insulating layer covers the third fan-out wire and the third insulating layer; and the first adapter portion and the second adapter portion are disposed on the fourth insulating layer.

11. A display panel, comprising:
a substrate, having a display area and a fan-out routing area located on one side of the display area;
a plurality of data lines, positioned in the display area;
a plurality of wiring groups, positioned in the fan-out routing area, wherein the wiring group comprises a first fan-out wire having a first fan-out segment, a second fan-out wire having a second fan-out segment, and a third fan-out wire having a third fan-out segment;
the first fan-out wire, second fan-out wire, and third fan-out wire are positioned in different layers; one of the data lines is connected to one of the fan-out wire, the second fan-out wire, and the third fan-out wire; one of the first fan-out wire, the second fan-out wire, and the third fan-out wire is provided on a same layer as the data lines; an extension direction of the first fan-out segment, the second fan-out segment and the third fan-out segment all intersect with an extension direction of the data line;
wherein in an orthographic projection direction of the substrate, the first fan-out segment is located on one side of the second fan-out segment, the third fan-out segment is located on another side of the second fan-out segment, a portion of the second fan-out segment is partially overlapped with a portion of the first fan-out segment, and a portion of the second fan-out segment is partially overlapped with a portion of the third fan-out segment.

12. The display panel of claim 11, wherein in one of the wiring groups, extension directions of the first fan-out segment, the second fan-out segment, and the third fan-out segment are parallel.

13. The display panel of claim 12, wherein in a direction from a side edge of the fan-out routing area to a middle of the fan-out routing area, an inclination angle of the first fan-out segment increases.

14. The display panel of claim 12, wherein in a direction from a side edge of the fan-out routing area to a middle of the fan-out routing area, lengths of the first fan-out segment, the second fan-out segment, and the third fan-out segment in a same wiring group sequentially decreases.

15. The display panel of claim 12, wherein in a direction from a side edge of the fan-out routing area to a middle of the fan-out routing area, lengths of the first fan-out segments in the plurality of wiring groups sequentially decreases.

16. The display panel of claim 11, wherein the first fan-out wire further comprises a first connection segment connected to one end of the first fan-out segment and a first binding segment connected to another end of the first fan-out segment; and extension directions of the first connection segment and the first binding segment both intersect the extension direction of the first fan-out segment;
wherein the second fan-out wire further comprises a second connecting segment connected to one end of the second fan-out segment and a second binding segment connected to another end of the second fan-out segment; and extension directions of the second connecting segment and the second binding segment both intersect the extension direction of the second fan-out segment;
wherein the third fan-out wire further comprises a third connecting segment connected to one end of the third fan-out segment and a third binding segment connected to the other end of the third fan-out segment; and extension directions of the third connecting segment and the third bound segment both intersect the extension direction of the third fan-out segment.

17. The display panel of claim 16, wherein the plurality of data lines include a first data line, a second data line and a third data line, the second fan-out wire is provided in a same layer as the data lines; the first fan-out wire is located below the second fan-out wire, and the third fan-out wire is located above the second fan-out wire;
wherein the display panel further comprises a first adapter portion and a second adapter portion located in a same layer, and the first adapter portion and the second adapter portion are located above the wiring groups;
wherein one end of the first adapter portion is connected to the first data line, another end of the first adapter portion is connected to the first connection segment; the second connection segment is directly connected to the second data line; one end of the second adapter portion is connected to the third data line, and another end of the second adapter portion is connected to the third connection segment.

18. The display panel of claim 17, further comprising a first insulating layer, a second insulating layer, a third insulating layer, and a fourth insulating layer; wherein the first insulating layer covers the first fan-out wire and the substrate; the data line and the second fan-out wire are disposed on the first insulating layer; the second insulating layer covers the second fan-out wire, the data line and the first insulating layer; the third insulating layer covers the second insulating layer; the third fan-out wire is disposed on the third insulating layer; the fourth insulating layer covers the third fan-out wire and the third insulating layer; and the first adapter portion and the second adapter portion are disposed on the fourth insulating layer.
